(19) United States
(12) Patent Application Publication
(10) Pub. No.: US 2023/0261074 A1
(43) Pub. Date: Aug. 17, 2023

(54) MULTIPLE DIPOLE OF DIFFERENT STRENGTHS IN GATE ALL AROUND TRANSISTOR

(71) Applicant: INTERNATIONAL BUSINESS MACHINES CORPORATION, ARMONK, NY (US)

(72) Inventors: Ruqiang Bao, Niskayuna, NY (US); Jingyun Zhang, Albany, NY (US); Jing Guo, Fremont, CA (US)

(21) Appl. No.: 17/650,671

(22) Filed: Feb. 11, 2022

(51) Int. Cl. H01L 29/423; H01L 29/06; H01L 29/786; H01L 29/66

(52) U.S. Cl. CPC H01L 29/42392; H01L 29/0665; H01L 29/66742; H01L 29/78696

(57) ABSTRACT

A semiconductor device including a first nanosheet device located on a substrate. The first nanosheet device includes a first plurality of nanosheets and each of the first plurality of nanosheets are surround by a first dipole. The first dipole has a first concentration of a first dipole material. A second nanosheet device located on the substrate. The second nanosheet device includes a second plurality of nanosheets and each of the second plurality of nanosheets are surround by a second dipole. The second dipole has a second concentration of a second dipole material. The first concentration and the second concentration are different.

### BACKGROUND

The present invention generally relates to the field of nano devices, and more particularly to adjusting the voltage for adjacent horizontal stacked nanosheets devices by forming a dipole around each of the nanosheets.

Nanosheet technology is the lead device architecture in continuing CMOS scaling. However, nanosheet technology has shown issues when manufacturing adjacent devices where the adjacent devices have a different voltage. The nanosheets are typically wrapped with a gate metal to adjust the voltage of the channels, but space is limited between the channels. Also, the gate metal is uniformly deposited on the nanosheets in adjacent devices, so it is hard for adjacent devices to have different voltages.

### BRIEF SUMMARY

Additional aspects and/or advantages will be set forth in part in the description which follows and, in part, will be apparent from the description, or may be learned by practice of the invention.

A semiconductor device including a first nanosheet device located on a substrate. The first nanosheet device includes a first plurality of nanosheets and each of the first plurality of nanosheets are surround by a first dipole. The first dipole has a first concentration of a first dipole material. A second nanosheet device located on the substrate. The second nanosheet device includes a second plurality of nanosheets and each of the second plurality of nanosheets are surround by a second dipole. The second dipole has a second concentration of a second dipole material. The first concentration and the second concentration are different.

A semiconductor device including a first nanosheet device located on a substrate. The first nanosheet device includes a first plurality of nanosheets and each of the first plurality of nanosheets are surround by a first dipole. The first dipole has a first concentration of a first dipole material. A second nanosheet device located on the substrate. The second nanosheet device includes a second plurality of nanosheets and each of the second plurality of nanosheets are surround by a second dipole. The second dipole has a second concentration of a second dipole material. The first concentration and the second concentration are different. A third nanosheet device located on the substrate and the third nanosheet device includes a third plurality of nanosheets. Each of the second plurality of nanosheets are surround by a third dipole. The third dipole has a third concentration of a third dipole material. The third concentration is different than the first concentration and the second concentration. A fourth nanosheet device located on the substrate and the fourth nanosheet device includes a fourth plurality of nanosheets. A dipole does not surround each of the fourth plurality of nanosheets.

A method including the steps of forming a first nanosheet device located on a substrate, wherein the first nanosheet device includes a first plurality of nanosheets. Forming a first interfacial layer surrounding each of the first plurality of nanosheets. Forming a first dielectric layer surrounding the first interfacial layer on each of the first plurality of nanosheets. Forming a first dipole around each of the first plurality of nanosheets and the first dipole has a first thickness. Forming a second nanosheet device located on the substrate, wherein the second nanosheet device includes a second plurality of nanosheets. Forming a second interfacial layer surrounding each of the second plurality of nanosheets. Forming a second dielectric layer surrounding the second interfacial layer on each of the second plurality of nanosheets. Forming a second dipole around each of the second plurality of nanosheets and the second dipole has a second thickness. The second thickness is greater than the first thickness.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross section of a plurality of nanosheet devices located on a common substrate, in accordance with an embodiment of the present invention.

FIG. 2 illustrates a cross section of a plurality of nanosheet devices located on a common substrate after one of the devices is isolated, in accordance with the embodiment of the present invention.

FIG. 3 illustrates a cross section of a plurality of nanosheet devices located on a common substrate after removal of the first dipole material layer from one of the devices, in accordance with the embodiment of the present invention.

FIG. 4 illustrates a cross section of a plurality of nanosheet devices located on a common substrate after removal of the lithography layer and the sacrificial layer, in accordance with the embodiment of the present invention.

FIG. 5 illustrates a cross section of a plurality of nanosheet devices located on a common substrate after formation of a second dipole layer, a second cover layer, and a second sacrificial layer, in accordance with the embodiment of the present invention.

FIG. 6 illustrates a cross section of a plurality of nanosheet devices located on a common substrate after removal of the second dipole material layer and the first dipole layer from one of the nanosheet devices, in accordance with the embodiment of the present invention.

FIG. 7 illustrates a cross section of a plurality of nanosheet devices located on a common substrate after removal of the second lithography layer and the second sacrificial layer, in accordance with the embodiment of the present invention.

FIG. 8 illustrates a cross section of a plurality of nanosheet devices located on a common substrate after formation of a third dipole layer, a third cover layer, and a third sacrificial layer, in accordance with the embodiment of the present invention.

FIG. 9 illustrates a cross section of a plurality of nanosheet devices located on a common substrate after removal of the first, the second, and the third dipole material layer from one of the nanosheet devices, in accordance with the embodiment of the present invention.

FIG. 10 illustrates a cross section of a plurality of nanosheet devices located on a common substrate after removal of the third lithography layer and the third sacrificial layer, in accordance with the embodiment of the present invention.

FIG. 11 illustrates a cross section of a plurality of nanosheet devices located on a common substrate after formation of a fourth sacrificial layer, in accordance with the embodiment of the present invention.

FIG. 12 illustrates a cross section of a plurality of nanosheet devices located on a common substrate after the annealing process and the removal of the fourth sacrificial layer, in accordance with the embodiment of the present invention.

FIG. 13 illustrates a cross section of a plurality of nanosheet devices located on a common substrate after the formation of the pFET, in accordance with the embodiment of the present invention.

FIG. 14 illustrates a cross section of a plurality of nanosheet devices located on a common substrate after the formation of the nFET, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. It is hard to implement multiple WFM’s for devices of the same polarity for stacked nanosheets due to the space limitation imposed by a desire of smaller Tsus (i.e., the distance between stacked nanosheets) to improve overall performance. Hence, there is a need for a multi-Vt solution that will work with a common WFM for devices of the same polarity providing a so-called “volumeless” solution that occupies little space. The “volumeless” solution is achieved by selectively depositing different amounts of dipole material around each of the nanosheets of the different devices. The dipole material deposited on each of the nanosheets can be comprised of the same material, different material, or a combination of materials. The amount of dipole material deposited can be the same amount or a different amount for each of the nanosheet devices. Once all the dipole material has been deposited then the nanosheets are put through an annealing process. The annealing process causes the dipole material to diffuse into the underlying layers that surround each of the nanosheets. The amount of the dipole material deposited on the nanosheets determines the concentration/gradient of dipole material located within the underlying layers. Thereby, the voltage of each of the nanosheet devices can be adjusted without infringing on the small amount of space separating each of the nanosheets.

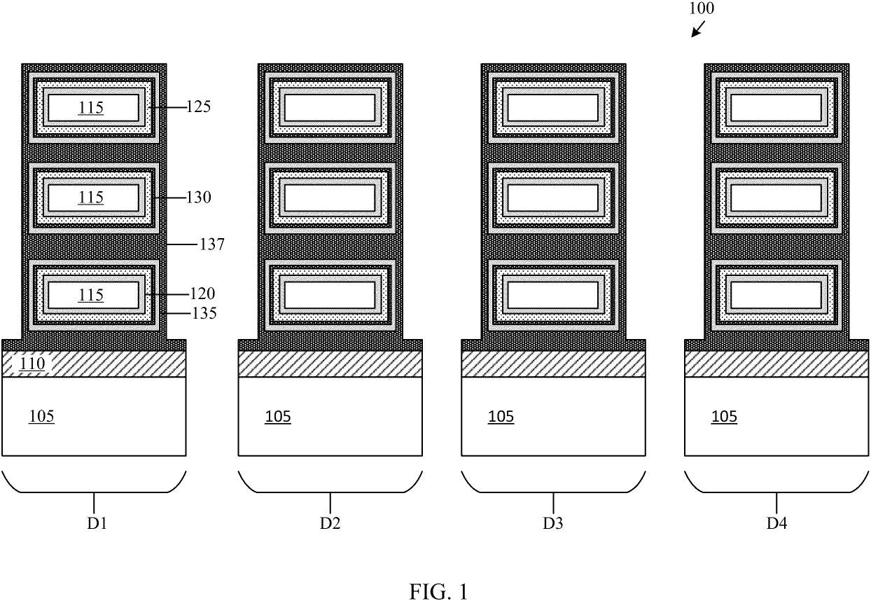

FIG. 1 illustrates a cross section of a plurality of nanosheet devices 100 located on a common substrate, in accordance with an embodiment of the present invention. FIG. 1 illustrates a cross section of a first nanosheet device D1, a second nanosheet device D2, a third nanosheet device D3, and a fourth nanosheet device D4. Each of the nanosheet devices (D1, D2, D3, and D4) are located on a common substrate 105. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or entire semiconductor substrate 105 may also be comprised of an amorphous, polycrystalline, or monocrystalline. The semiconductor substrate 105 may be doped, undoped or contain doped regions and undoped regions therein. Each of the devices (D1, D2, D3, and D4) are comprised of a plurality of nanosheets 115. FIG. 1 illustrates that each nanosheet device (D1, D2, D3, and D3) includes three nanosheets 115, but this is for illustrative purposes only. Each nanosheet device (D1, D2, D3, and D4) can include fewer or more than three nanosheets 115. The nanosheet 115 can be comprised of, for example, Si. A first layer 110 is located on top of the substrate 105, and the nanosheets are located above the first layer 110. Each of the nanosheets are surrounded by an interfacial layer 120. The interfacial layer 120 can be comprised of, for example, an oxide or another suitable material. A gate dielectric 125 is located around each of the interfacial layer 120. The gate dielectric 125 can be comprised of, for example, SiN. A first dipole material layer 130 is located around each of the gate dielectric 125. The first dipole material layer 130 is a relatively thin layer, having a thickness in the range of 1 to 20 Angstroms. The first dipole material layer 130 can be comprised of a material selected from a group consisting of La₂O₃, Y₂O₃, Al₂O₃, an element from Group IIIB, or an element from Group IVB, or an element from Group VB, or an element from the Lanthanide Series, or an element from Group VIII of the Periodic Table of Elements, or a combination thereof. A first cover layer 135 surrounds each of the first dipole material layer 130. The first cover layer 135 can be comprised of, for example, TiN. A sacrificial layer 137 is located all around each of the first cover layers 135 and on top of the first layer 110.

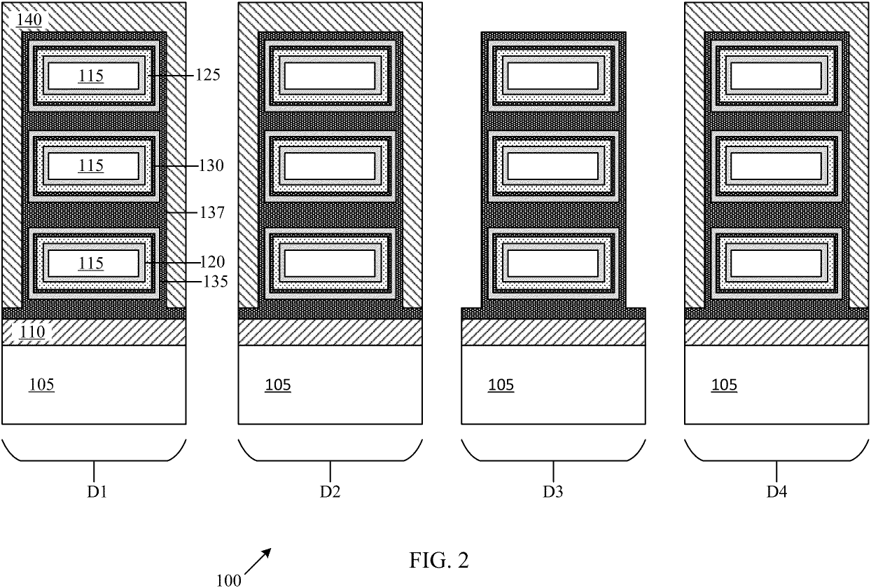

FIG. 2 illustrates a cross section of a plurality of nanosheet devices 100 located on a common substrate 105 after one of the devices is isolated, in accordance with the embodiment of the present invention. A lithography layer 140 is located on top of the sacrificial layer 137. The lithography layer 140 is patterned to expose the sacrificial layer 137 of one of the nanosheet devices D3. Nanosheet device D3 is exposed or isolated from the other nanosheet devices D1, D2 and D4 to allow for the processing of only nanosheet device D3. FIG. 2 illustrates that nanosheet device D3 was isolated first, but this is only meant as an example, any of the nanosheet devices can be isolated first. Furthermore, if is desired to have two or more nanosheet devices having a same voltage, then more than one nanosheet device can be isolated/exposed at a time.

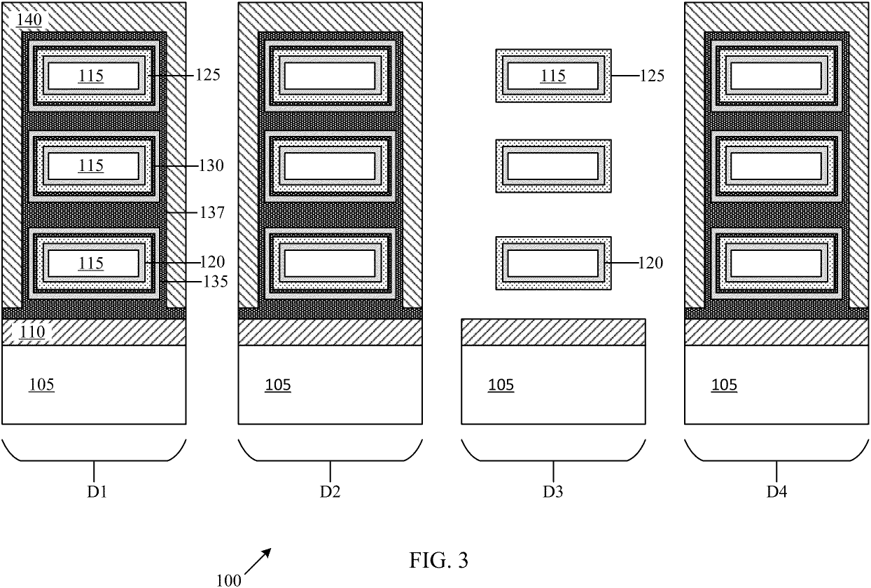

FIG. 3 illustrates a cross section of a plurality of nanosheet devices 100 located on a common substrate 105 after removal of the first dipole material layer 130 from one of the nanosheet devices D3, in accordance with the embodiment of the present invention. Nanosheet device D3 is etched to remove the first dipole material layer 130. FIG. 3 illustrates that the etching process removes the first dipole material layer 130 around each of the nanosheets 115 of nanosheet device D3, while leaving the gate dielectric 125 and the interfacial layer 120 untouched.

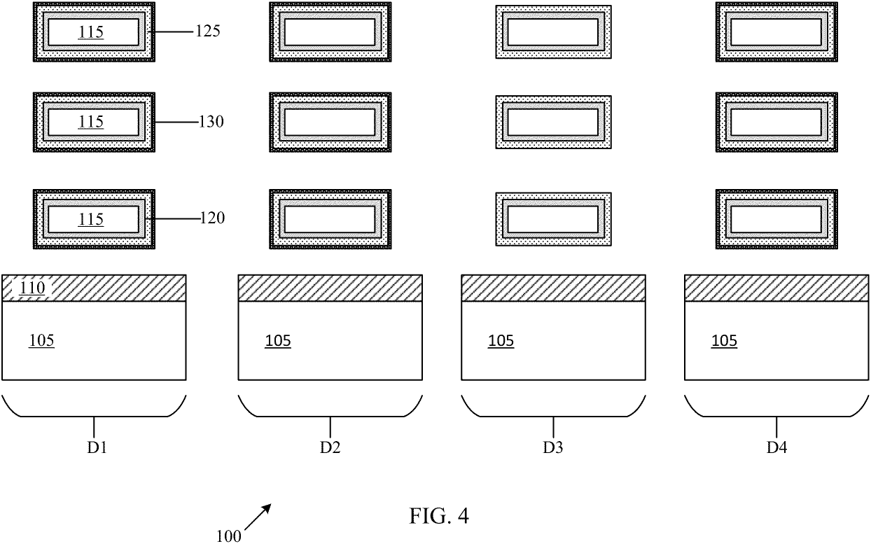

FIG. 4 illustrates a cross section of a plurality of nanosheet devices 100 located on a common substrate after removal of the lithography layer 140, the sacrificial layer 137, and the cover layer 135, in accordance with the embodiment of the present invention. The lithography layer 140, the sacrificial layer 137, and the cover layer 135 are removed to expose the first dipole material layer 130 located on the nanosheets 115 of each of the nanosheet devices (D1, D2, and D4). The gate dielectric 125 located on each of the nanosheets 115 of nanosheet device D3 is exposed.

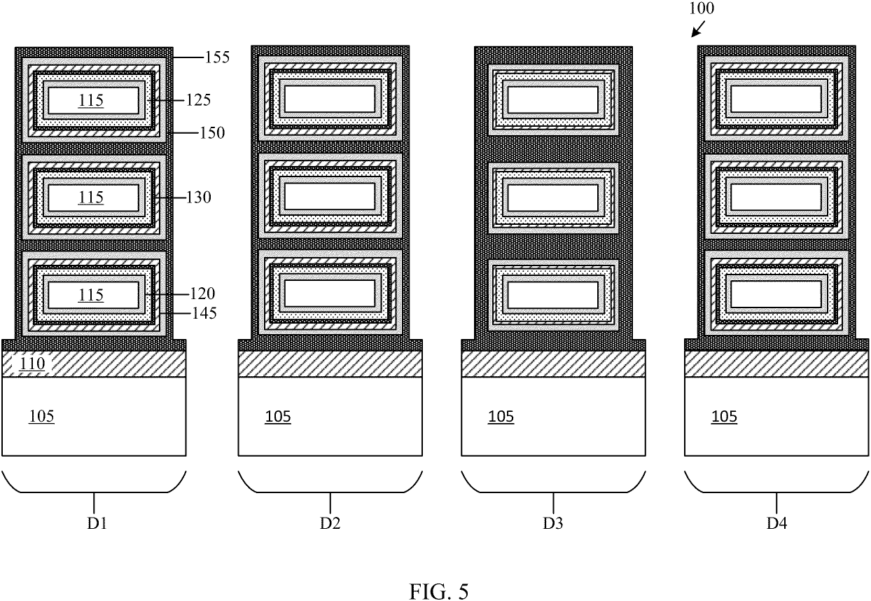

FIG. 5 illustrates a cross section of a plurality of nanosheet devices 100 located on a common substrate 105 after formation of a second dipole layer 145, a second cover layer 150, and a second sacrificial layer 155, in accordance with the embodiment of the present invention. A second dipole material layer 145 is located around the first dipole material layer 130 located on the nanosheets 115 of each of the nanosheet devices D1, D2, and D4. The second dipole material layer 145 is located around the gate dielectric 125 on nanosheet device D3. The second dipole material layer 145 is a relatively thin layer, having a thickness in the range of 1 to 20 Angstroms. The second dipole material layer 145 can be comprised of a material selected from a group consisting of La₂O₃, Y₂O₃, Al₂O₃, an element from Group IIIB, or an element from Group IVB, or an element from Group VB, or an element from the Lanthanide Series, or an element from Group VIII of the Periodic Table of Elements, or a combination thereof. The second dipole material layer 145 can be comprised of the same material or a different material as the first dipole material layer 130. A second cover layer 150 surrounds each of the second dipole material layer 145 on nanosheet devices D1, D2, D3, and D4. The second cover layer 150 can be comprised of, for example, TiN. A second sacrificial layer 155 is located all around each of the second cover layers 150 and on top of the first layer 110.

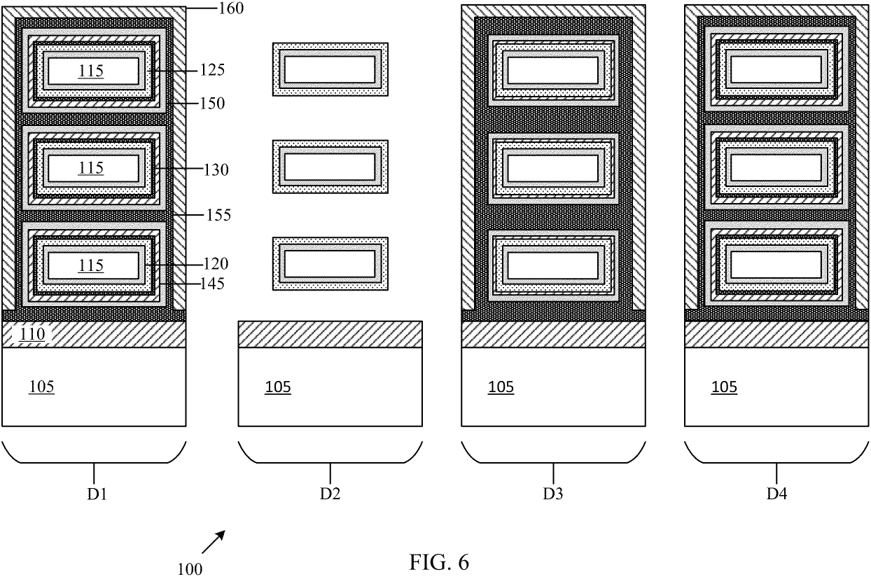

FIG. 6 illustrates a cross section of a plurality of nanosheet devices 100 located on a common substrate after removal of the second dipole material layer 145 and the first dipole material layer 130 from one of the nanosheet devices, in accordance with the embodiment of the present invention. A second lithography layer 160 is formed on top of the second sacrificial layer 155. The second lithography layer 160 is patterned to isolate/expose one of the nanosheet devices (D2). The first dipole material layer 130 and the second dipole material layer 145 is etched/removed from the nanosheet device (D2). FIG. 6 illustrates that the etching process removes the first dipole material layer 130 and the second dipole material layer 145 around each of the nanosheets 115 of nanosheet device D2, while leaving the gate dielectric 125 and the interfacial layer 120 untouched.

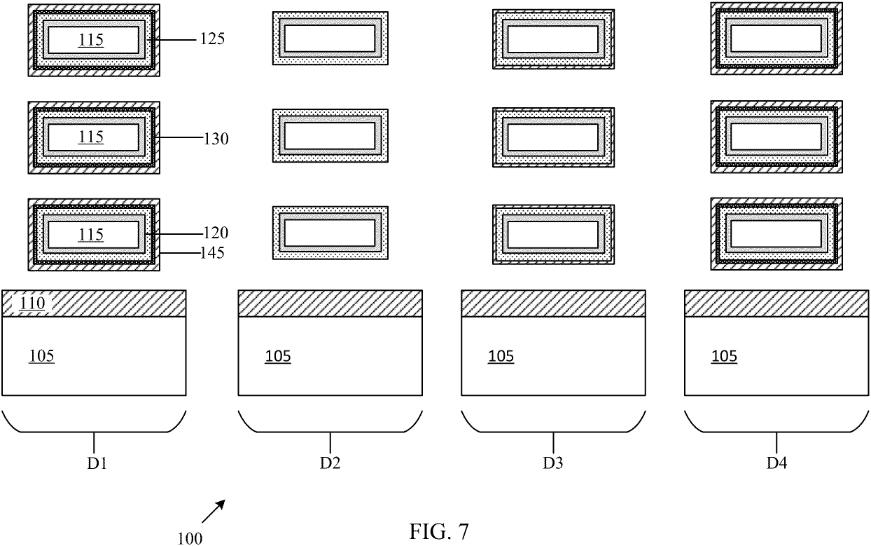

FIG. 7 illustrates a cross section of a plurality of nanosheet devices 100 located on a common substrate after removal of the second lithography layer 160, the second sacrificial layer 155, and the second cover layer 150, in accordance with the embodiment of the present invention. The second lithography layer 160, the second sacrificial layer 155, and the second cover layer 150 are removed to expose the second dipole material layer 145 located on the nanosheets 115 of each of the nanosheet device (D1, D3, and D4). The gate dielectric 125 located on each of the nanosheets 115 of nanosheet device D2 is exposed. These layers are exposed to all for the formation of the next dipole layer.

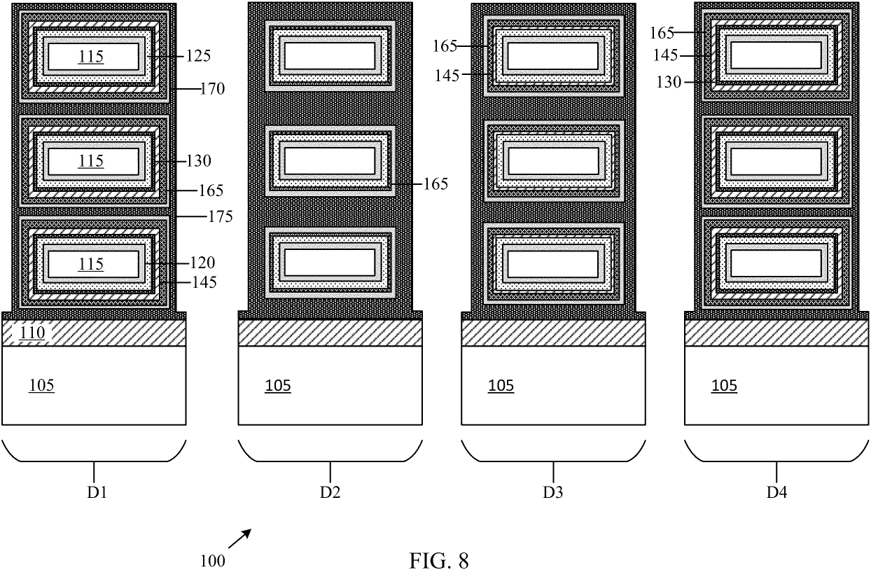

FIG. 8 illustrates a cross section of a plurality of nanosheet devices located on a common substrate after formation of a third dipole material layer 165, a third cover layer 170, and a third sacrificial layer 175, in accordance with the embodiment of the present invention. A third dipole material layer 165 is located around the second dipole material layer 145 located on the nanosheets 115 of each of the on nanosheet devices D1, D3, and D4. The third dipole material layer 165 is located around the gate dielectric 125 on nanosheet device D2. The third dipole material layer 165 is a relatively thin layer, having a thickness in the range of 1 to 20 Angstroms. The third dipole material layer 165 can be comprised of a material selected from a group consisting of La₂O₃, Y₂O₃, Al₂O₃, an element from Group IIIB, or an element from Group IVB, or an element from Group VB, or an element from the Lanthanide Series, or an element from Group VIII of the Periodic Table of Elements, or a combination thereof. The third dipole material layer 165 can be comprised of the same material or a different material as the first dipole material layer 130 and/or the second dipole material layer 145. A third cover layer 170 surrounds each of the third dipole material layer 165 on nanosheet devices D1, D2, D3, and D4. The third cover layer 170 can be comprised of, for example, TiN. A third sacrificial layer 175 is located all around each of the third cover layers 170 and on top of the first layer 110.

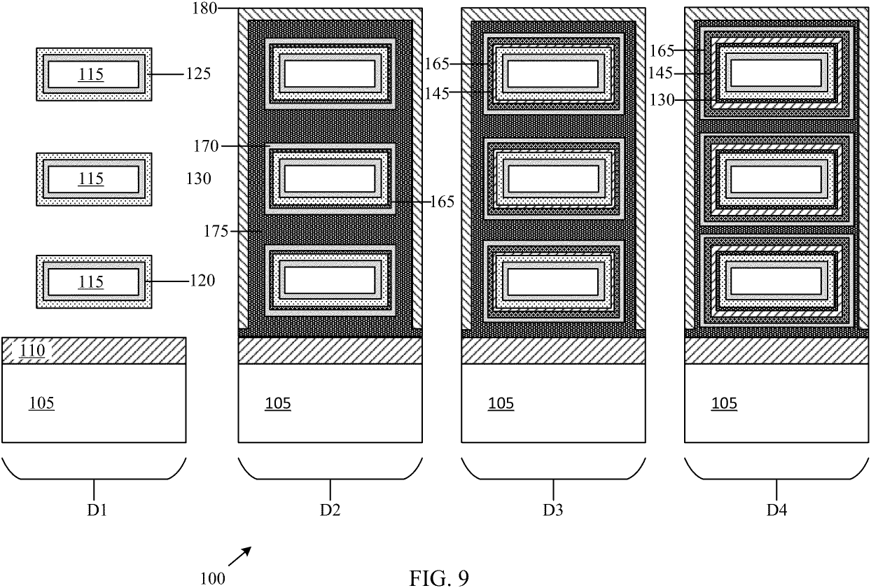

FIG. 9 illustrates a cross section of a plurality of nanosheet devices 100 located on a common substrate 105 after removal of the first, the second, and the third dipole material layer (130, 145, and 165) from one of the nanosheet devices D1, in accordance with the embodiment of the present invention. A third lithography layer 180 is formed on top of the third sacrificial layer 175. The third lithography layer 180 is patterned to isolate/expose one of the nanosheet devices (D1). The first dipole material layer 130, the second dipole material layer 145, and the third dipole material layer 165 is etched/removed from the nanosheet device (D1). FIG. 9 illustrates that the etching process removes the first dipole material layer 130, the second dipole material layer 145, and the third dipole layer 164 around each of the nanosheets 115 of nanosheet device D1, while leaving the gate dielectric 125 and the interfacial layer 120 untouched.

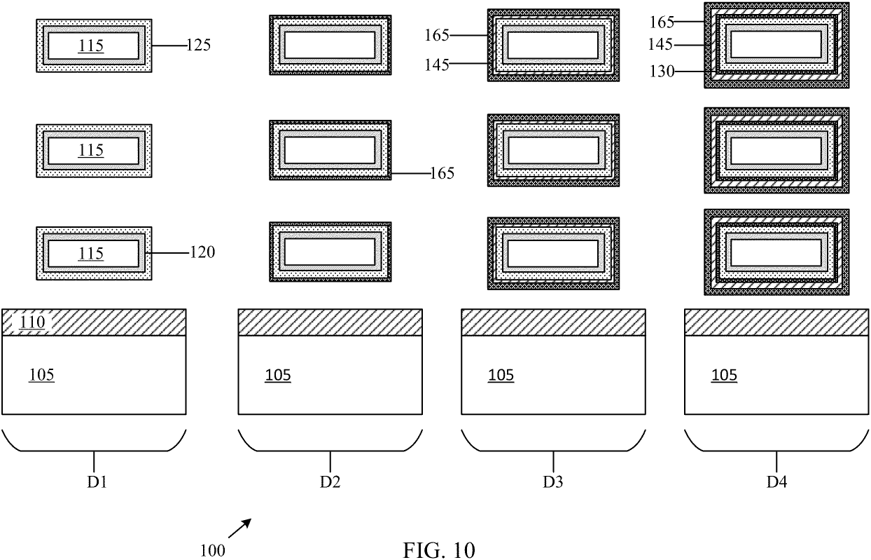

FIG. 10 illustrates a cross section of a plurality of nanosheet devices located on a common substrate after removal of the third lithography layer 180, the third sacrificial layer 175, and the third cover layer 170 in accordance with the embodiment of the present invention. The third lithography layer 180, the third sacrificial layer 175, and the third cover layer 170 are removed to expose the third dipole material layer 165 located on the nanosheets 115 of each of the nanosheet device (D2, D3, and D4). The gate dielectric 125 located on each of the nanosheets 115 of nanosheet device D1 is exposed. The amount of dipole material varies from nanosheet device to nanosheet device (D1, D2, D3, and D4). For example, nanosheet device D4 has the largest amount of dipole material located thereon (the first dipole material layer 130, the second dipole material layer 145, and the third dipole material layer 165). The amount of dipole material is determined by the amount/number of dipole material layers that remain on each device after the completion of the deposition process. The final amount of dipole material located on each of the devices affects the final concentration/gradient of the dipole material located in the gate dielectric 125 and the interfacial layer 120.

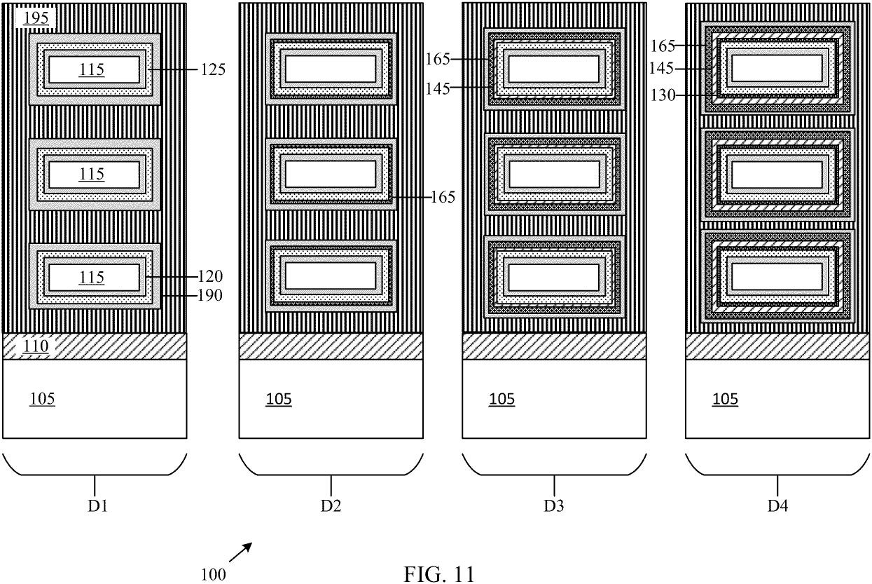

FIG. 11 illustrates a cross section of a plurality of nanosheet devices 100 located on a common substrate 105 after formation of a fourth sacrificial layer 195, in accordance with the embodiment of the present invention. A fourth cover layer 190 surrounds each of the third dipole material layer 165 located on each of the nanosheets 115 of nanosheet devices D2, D3, and D4 and the fourth cover layer 190 surrounds the gate dielectric 125 located on each of the nanosheets 115 of nanosheet device D1. The fourth cover layer 190 can be comprised of, for example, TiN. A fourth sacrificial layer 195 encloses each of the nanosheet devices (D1, D2, D3, and D4). The fourth sacrificial layer 195 can be comprised of, for example, amorphous-Si. The nanosheet devices 100 undergoes an annealing process to cause the dipole material layers to diffuse into the gate dielectric 125 and the interfacial layer 120.

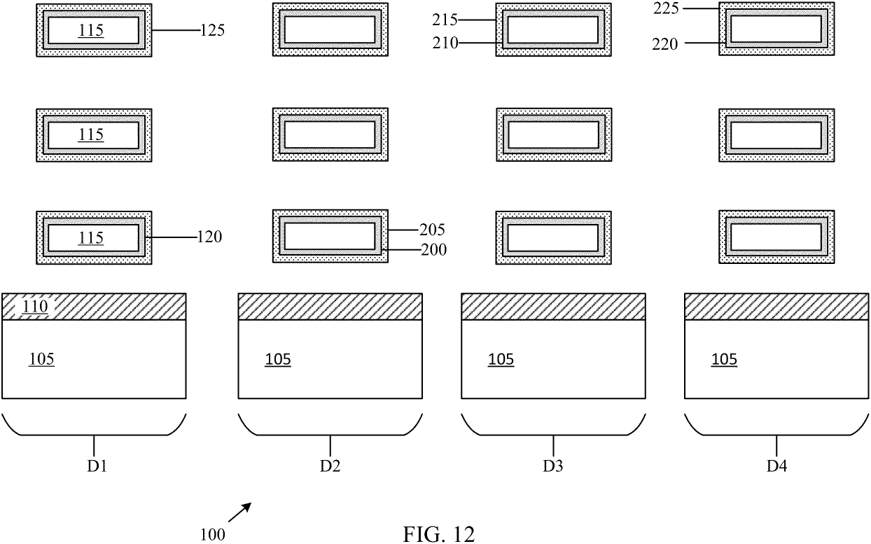

FIG. 12 illustrates a cross section of a plurality of nanosheet devices 100 located on a common substrate 105 after the annealing process and the removal of the fourth sacrificial layer 195, in accordance with the embodiment of the present invention. The nanosheet devices 100 undergoes an annealing process to cause the dipole material (the first dipole material layer 130, the second dipole material layer 145, and the third dipole material layer 165) to diffuse into the gate dielectric 125 and the interfacial layer 120. The concentration of the dipole material in the gate dielectric 125 and the interfacial layer 120 will be different between the nanosheet devices D1, D2, D3, and D4. The gate dielectric 225 and the interfacial layer 220 located on each of the nanosheets 115 of nanosheet device D4 will have the highest concentration/gradient of the dipole material because the first dipole material layer 130, the second dipole material layer 145, and the third dipole material layer 165 were located on the nanosheets 115 of the nanosheet device D4 prior to the annealing process. The gate dielectric 215 and the interfacial layer 210 located on each of the nanosheets 115 of nanosheet device D3 will have a lower concentration/gradient of dipole material than nanosheet device D4 because the second dipole material layer 145, and the third dipole material layer 165 were located on each of the nanosheets 115 of nanosheet device D3 prior to the annealing process. The gate dielectric 205 and the interfacial layer 200 located on each of the nanosheets 115 of nanosheet device D2 will have a lower concentration/gradient of dipole material than nanosheet device D3 because only the third dipole material layer 165 was located on each of the nanosheets 115 of nanosheet device D2 prior to the annealing process. The gate dielectric 125 and the interfacial layer 120 of nanosheet device D1 remains unchanged because there was no dipole material located on each of the nanosheets 115 of nanosheet device D1 prior to the annealing process. The final dipoles formed in each of the layers (200, 205, 210, 215, 220, 225) can have the same polarity. However, the dipoles vary in strength between nanosheet devices (D1, D2, D3, and D4) because of the difference of dipole material concentrations located around each of the nanosheets 115 of each of the nanosheet device D1, D2, D3, and D4. By having the dipoles of different strength allows for the voltage for the nanosheets 115 to be vary between the nanosheet devices (D1, D2, D3, and D4).

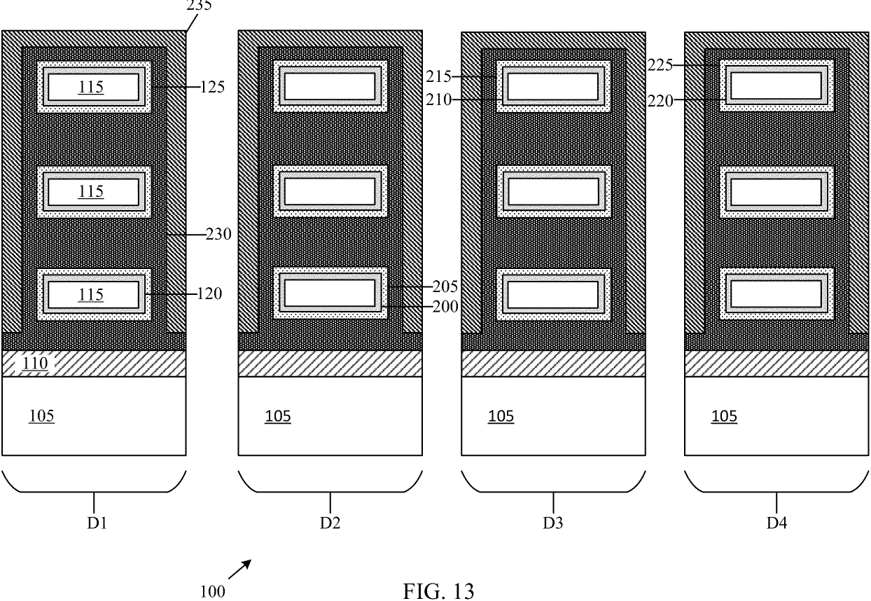

FIG. 13 illustrates a cross section of a plurality of nanosheet devices 100 located on a common substrate 105 after the formation of the pFET, in accordance with the embodiment of the present invention. An encapsulation layer 230 is formed around the gate dielectric 125 and the dipole gate dielectric 205, 215, and 225 on each of the nanosheet devices D1, D2, D3, and D4. The encapsulation layer 230 can be comprised of, for example, a metal nitride. A gate metal layer 235 is formed on top of the encapsulation layer 230. In one embodiment, the gate metal layer 235 can be comprised of, for example, a nFET work metal or work metal stack which contains Ti or Al. The final dipoles formed in each of the layers (200, 205, 210, 215, 220, 225) can have the same polarity. However, the dipoles vary in strength between nanosheet devices (D1, D2, D3, and D4). By having the dipoles of different strength allows for the voltage for the nanosheets 115 to be vary between the nanosheet devices (D1, D2, D3, and D4).

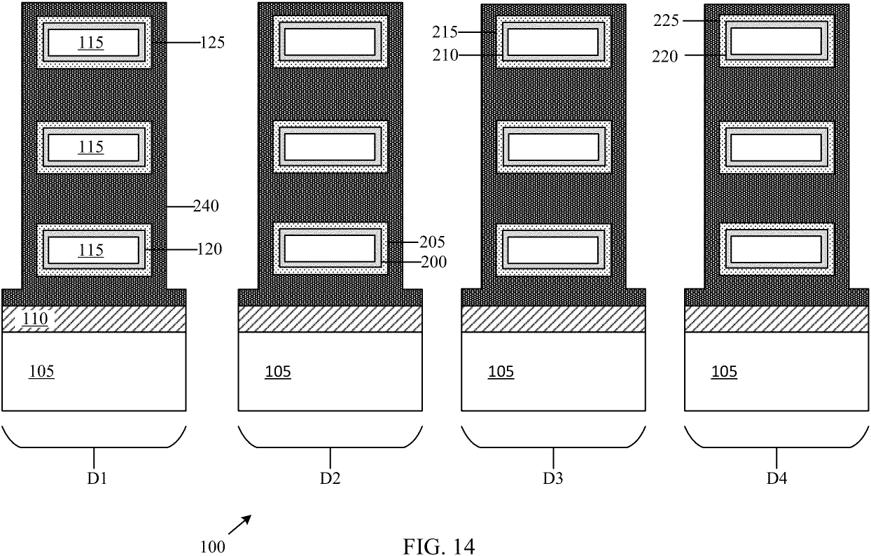

FIG. 14 illustrates a cross section of a plurality of nanosheet devices 100 located on a common substrate 105 after the formation of the nFET, in accordance with the embodiment of the present invention. A gate metal 240 is formed around the gate dielectric 125 and the dipole gate dielectric 205, 215, and 225 on each of the nanosheet devices D1, D2, D3, and D4. The final dipoles formed in each of the layers (200, 205, 210, 215, 220, 225) can have the same polarity. However, the dipoles vary in strength between nanosheet devices (D1, D2, D3, and D4). By having the dipoles of different strength allows for the voltage for the nanosheets 115 to be vary between the nanosheet devices (D1, D2, D3, and D4). The gate metal 240 can be comprised of, for example, a gate metal stack which is composed of multiple gate metal layers, Ti or Al. In one embodiment, the gate metal 240 is the same material as the gate metal layer 235.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
a first nanosheet device located on a substrate, wherein the first nanosheet device includes a first plurality of nanosheets, wherein each of the first plurality of nanosheets are surround by a first dipole, wherein the first dipole has a first concentration of a first dipole material; and
a second nanosheet device located on the substrate, wherein the second nanosheet device includes a second plurality of nanosheets, wherein each of the second plurality of nanosheets are surround by a second dipole, wherein the second dipole has a second concentration of a second dipole material, wherein the first concentration and the second concentration are different.

2. The semiconductor device of claim 1, further comprising:
a first interfacial layer surrounding each of the first plurality of nanosheets;
a first dielectric layer surrounding the first interfacial layer on each of the first plurality of nanosheets, wherein the first dipole material is located within the first interfacial layer and the first dielectric layer.

3. The semiconductor device of claim 2, further comprising:
a second interfacial layer surrounding each of the second plurality of nanosheets;
a second dielectric layer surrounding the second interfacial layer on each of the second plurality of nanosheets, wherein the second dipole material is located within the second interfacial layer and the second dielectric layer.

4. The semiconductor device of claim 3, wherein an amount of the first dipole material located within the first interfacial layer and the first dielectric layer is different than an amount of second dipole material located within the second interfacial layer and the second dielectric layer.

5. The semiconductor device of claim 4, wherein the first dipole material and the second dipole material are comprised of different dipole materials.

6. The semiconductor device of claim 4, wherein the first dipole material and the second dipole material are comprised of the same dipole materials.

7. The semiconductor device of claim 4, wherein the first dipole material and the second dipole material are comprised of different amounts of the same dipole material.

8. The semiconductor device of claim 1, wherein the first dipole material is comprised of a dipole material selected from a group consisting of La₂O₃, Y₂O₃, Al₂O₃, or a combination thereof.

9. The semiconductor device of claim 1, wherein the second dipole material is comprised of a dipole material selected from a group consisting of La₂O₃, Y₂O₃, Al₂O₃, or a combination thereof.

10. A semiconductor device comprising:
a first nanosheet device located on a substrate, wherein the first nanosheet device includes a first plurality of nanosheets, wherein each of the first plurality of nanosheets are surround by a first dipole, wherein the first dipole has a first concentration of a first dipole material;
a second nanosheet device located on the substrate, wherein the second nanosheet device includes a second plurality of nanosheets, wherein each of the second plurality of nanosheets are surround by a second dipole, wherein the second dipole has a second concentration of a second dipole material, wherein the first concentration and the second concentration are different;
a third nanosheet device located on the substrate, wherein the third nanosheet device includes a third plurality of nanosheets, wherein each of the second plurality of nanosheets are surround by a third dipole, wherein the third dipole has a third concentration of a third dipole material, wherein the third concentration is different than the first concentration and the second concentration; and
a fourth nanosheet device located on the substrate, wherein the fourth nanosheet device includes a fourth plurality of nanosheets, wherein a dipole does not surround each of the fourth plurality of nanosheets.

11. The semiconductor device of claim 10, further comprising:
a first interfacial layer surrounding each of the first plurality of nanosheets;
a first dielectric layer surrounding the first interfacial layer on each of the first plurality of nanosheets, wherein the first dipole material is located within the first interfacial layer and the first dielectric layer.

12. The semiconductor device of claim 11, further comprising:
a second interfacial layer surrounding each of the second plurality of nanosheets;
a second dielectric layer surrounding the second interfacial layer on each of the second plurality of nanosheets, wherein the second dipole material is located within the second interfacial layer and the second dielectric layer.

13. The semiconductor device of claim 12, further comprising:
a third interfacial layer surrounding each of the third plurality of nanosheets;
a third dielectric layer surrounding the third interfacial layer on each of the third plurality of nanosheets, wherein the third dipole material is located within the third interfacial layer and the third dielectric layer.

14. The semiconductor device of claim 13, wherein an amount of the first dipole material located within the first interfacial layer and the first dielectric layer is different than an amount of second dipole material located within the second interfacial layer and the second dielectric layer.

15. The semiconductor device of claim 14, wherein an amount of the first dipole material located within the first interfacial layer and the first dielectric layer is different than an amount of second third material located within the third interfacial layer and the third dielectric layer.

16. The semiconductor device of claim 15, wherein an amount of the third dipole material located within the third interfacial layer and the third dielectric layer is different than an amount of second dipole material located within the second interfacial layer and the second dielectric layer.

17. A method comprising:
forming a first nanosheet device located on a substrate, wherein the first nanosheet device includes a first plurality of nanosheets,
forming a first interfacial layer surrounding each of the first plurality of nanosheets;
forming a first dielectric layer surrounding the first interfacial layer on each of the first plurality of nanosheets;
forming a first dipole around each of the first plurality of nanosheets, wherein the first dipole has a first thickness;
forming a second nanosheet device located on the substrate, wherein the second nanosheet device includes a second plurality of nanosheets,
forming a second interfacial layer surrounding each of the second plurality of nanosheets;
forming a second dielectric layer surrounding the second interfacial layer on each of the second plurality of nanosheets; and
forming a second dipole around each of the second plurality of nanosheets, wherein the second dipole has a second thickness, wherein the second thickness is greater than the first thickness.

18. The method of claim 17, further comprising:
annealing the first nanosheet device and the second nanosheet device causing the first dipole to diffuse in to the first interfacial layer and the first dielectric layer, and causing the second dipole to diffuse in to the second interfacial layer and the second dielectric layer.

19. The method of claim 17, wherein the second dipole includes the first dipole.

20. The method of claim 17, wherein the first dipole consists of a first dipole material and the second dipole consists of a second dipole material, wherein the first dipole material and the second dipole material are different.
